(19) United States
(12) Patent Application Publication
(10) Pub. No.: US 2022/0139730 A1
(43) Pub. Date: May 5, 2022

(54) MULTI-CHANNEL LIQUID DELIVERY SYSTEM FOR ADVANCED SEMICONDUCTOR APPLICATIONS

(71) Applicant: LAM RESEARCH CORPORATION, Fremont, CA (US)

(72) Inventors: Miguel Benjamin VASQUEZ, Portland, OR (US); Jonathan CHURCH, Portland, OR (US); Keith FOX, Tigard, OR (US)

(21) Appl. No.: 17/424,306

(22) PCT Filed: Jan. 29, 2020
(86) PCT No.: PCT/US2020/015589

§ 371 Date: Jul. 20, 2021

Related U.S. Application Data
(60) Provisional application No. 62/799,584, filed on Jan. 31, 2019.

(51) Int. Cl. H01L 21/67; H01J 37/32; C23C 16/44

(52) U.S. Cl. CPC H01L 21/67023; C23C 16/4404; H01J 37/32449

(57) ABSTRACT

An apparatus comprises a first liquid input line, a second liquid input line, a third liquid input line, a first liquid flow controller with an input in fluid contact with the first liquid input line, a second liquid flow controller with an input in fluid contact with the second liquid input line, a third liquid flow controller with an input in fluid contact with the third liquid input line, a common manifold in fluid contact with an output of the first liquid flow controller and an output of the second liquid flow controller and an output of the third liquid flow controller, and a vaporizer with an input in fluid contact with the common manifold.

### CROSS-REFERENCE TO RELATED APPLICATION

This application claims the benefit of priority of U.S. application Ser. No. 62/799,584, filed Jan. 31, 2019, which is incorporated herein by reference for all purposes.

### BACKGROUND

The disclosure relates to plasma processing chambers for plasma processing a wafer. More specifically, the disclosure relates to plasma processing chambers that use vaporized liquid chemistry.

Plasma processing is used in forming semiconductor devices. During the plasma processing vaporized liquids may be used.

### SUMMARY

To achieve the foregoing and in accordance with the purpose of the present disclosure, an apparatus is provided. The apparatus comprises a first liquid input line, a second liquid input line, a third liquid input line, a first liquid flow controller with an input in fluid contact with the first liquid input line, a second liquid flow controller with an input in fluid contact with the second liquid input line, a third liquid flow controller with an input in fluid contact with the third liquid input line, a common manifold in fluid contact with an output of the first liquid flow controller and an output of the second liquid flow controller and an output of the third liquid flow controller, and a vaporizer with an input in fluid contact with the common manifold.

These and other features of the present disclosure will be described in more detail below in the detailed description of the disclosure and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a schematic view of an embodiment.

FIG. 2 is a schematic view of a plasma processing chamber according to an embodiment.

### DETAILED DESCRIPTION OF THE EXEMPLARY EMBODIMENTS

The present disclosure will now be described in detail with reference to a few preferred embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well-known process steps and/or structures have not been described in detail in order to not unnecessarily obscure the present disclosure.

In some plasma processing processes, a vapor from a mixture of at least three liquids mixed together is used during the plasma processing. The mixture of liquids may be provided as a liquid mixture in an enclosed container to a plasma processing system. The liquid mixture would have a predetermined ratio of components. The liquid mixture is drawn from the enclosed container and vaporized. When the container is emptied, the container is removed and a new container of each liquid is provided. The use of a removable container is cumbersome. In addition, fractions of different liquids in the liquid mixture are difficult to change.

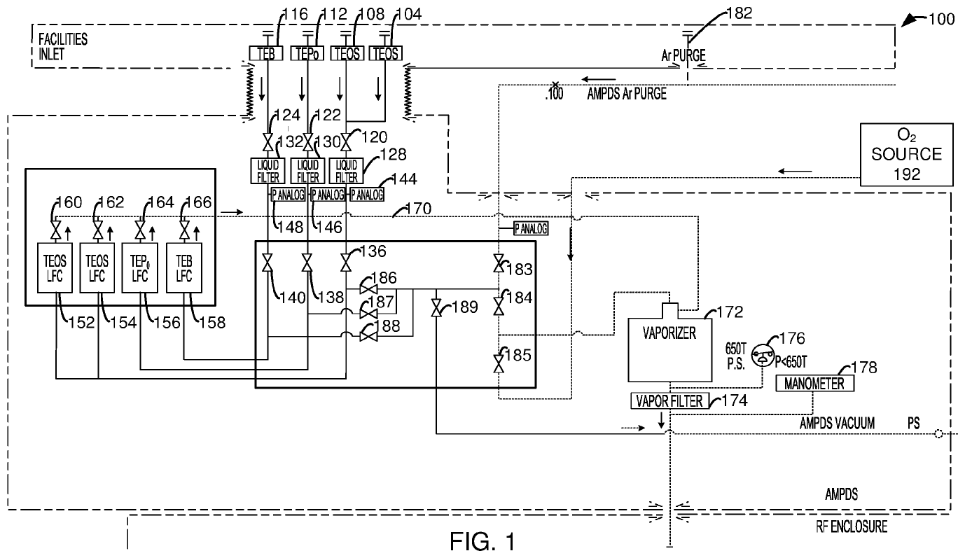

FIG. 1 is a schematic view of an embodiment of a multi-channel liquid delivery system 100 for a plasma processing chamber. In this embodiment, a first liquid input line 104, a second liquid input line 108, a third liquid input line 112, and a fourth liquid input line 116 are provided. In this example, the first liquid input line 104 and the second liquid input line 108 provide liquid tetraethyl orthosilicate (TEOS). The use of a first liquid input line 104 and a second liquid input line 108 provide a higher flow of liquid TEOS than a single liquid input line. The third liquid input line 112 provides a liquid TEOS doped with phosphorous (TEPo). The fourth liquid input line 116 provides a liquid TEOS doped with boron (TEB).

The first liquid input line 104 and the second liquid input line 108 provide input to a first lock out tag out valve 120. The third liquid input line 112 provides input to a second lock out tag out valve 122. The fourth liquid input line 116 provides input to a third lock out tag out valve 124. Output from the first lock out tag out valve 120 is provided as input to a first liquid filter 128. Output from the second lock out tag out valve 122 is provided as input to a second liquid filter 130. Output from the third lock out tag out valve 124 is provided as input to a third liquid filter 132. Output from the first liquid filter 128 is provided as input to a first input valve 136. Output from the second liquid filter 130 is provided as input to a second input valve 138. Output from the third liquid filter 132 is provided as input to a third input valve 140. A first pressure manometer 144 measures pressure between the first liquid filter 128 and the first input valve 136. A second pressure manometer 146 measures pressure between the second liquid filter 130 and the second input valve 138. A third pressure manometer 148 measures pressure between the third liquid filter 132 and the third input valve 140.

Output from the first input valve 136 is provided as input to a first liquid flow controller 152 and a second liquid flow controller 154. The first liquid flow controller 152 and the second liquid flow controller 154 are in fluid contact with the first liquid input line 104 and the second liquid input line 108. The first liquid filter 128 is in fluid communication between the first and second liquid input lines 104, 108 and the first and second liquid flow controllers 152, 154. Output from the second input valve 138 is provided as input to a third liquid flow controller 156. The third liquid flow controller 156 is in fluid contact with the third liquid input line 112. The second liquid filter 130 is in fluid communication between the third liquid input line 112 and the third liquid flow controller 156. Output from the third input valve 140 is provided as input to a fourth liquid flow controller 158. The fourth liquid flow controller 158 is in fluid contact with the fourth liquid input line 116. The third liquid filter 132 is in fluid communication between the fourth liquid input line 116 and the fourth liquid flow controller 158. Output from the first liquid flow controller 152 is provided as input for a first output valve 160. Output from the second liquid flow controller 154 is provided as input for a second output valve 162. Output from the third liquid flow controller 156 is provided as input for a third output valve 164. Output from the fourth liquid flow controller 158 is provided as input for a fourth output valve 166.

Output from the first output valve 160, the second output valve 162, the third output valve 164, and the fourth output valve 166 is provided to a common manifold 170. The common manifold 170 is in fluid contact with the first liquid flow controller 152, the second liquid flow controller 154, the third liquid flow controller 156, and the fourth liquid flow controller 158. The common manifold 170 provides input to a vaporizer 172. The input of the vaporizer 172 is in fluid contact with the common manifold 170. The vaporizer 172 provides input to a vapor filter 174. The vapor filter 174 provides vapor to an inlet of a plasma processing chamber. An output of the vaporizer 172 is in fluid contact with the inlet to the plasma processing chamber. A pressure switch 176 may measure pressure between the vaporizer 172 and the vapor filter 174. A vapor manometer 178 may measure the pressure of vapor from the vapor filter 174. The vapor filter 174 may be heated to improve vaporization.

To provide a purge system for the multi-channel liquid delivery system 100 has a purge gas input line 182. A first purge valve 183 receives input from the purge gas input line 182. Output from the first purge valve 183 is provided as input to a second purge valve 184. Output from the second purge valve 184 is connected to a third purge valve 185 and the vaporizer 172. Output from the first purge valve 183 is also provided as input to a fourth purge valve 186, a fifth purge valve 187, a sixth purge valve 188, and a seventh purge valve 189. Output of the fourth purge valve 186 is provided between the output of the first input valve 136 and the input of the first liquid flow controller 152 and the second liquid flow controller 154. Output of the fifth purge valve 187 is provided between the output of the second input valve 138 and the input of the third liquid flow controller 156. Output of the sixth purge valve 188 is provided between the output of the third input valve 140 and the input of the fourth liquid flow controller 158. Output of the seventh purge valve 189 is provided to a vacuum system. The purge gas input line 182 is in fluid contact with the first liquid flow controller 152, the second liquid flow controller 154, the third liquid flow controller 156, the fourth liquid flow controller 158, and the vaporizer 172. An O₂ source 192 provides an O₂ carrier gas to the third purge valve 185.

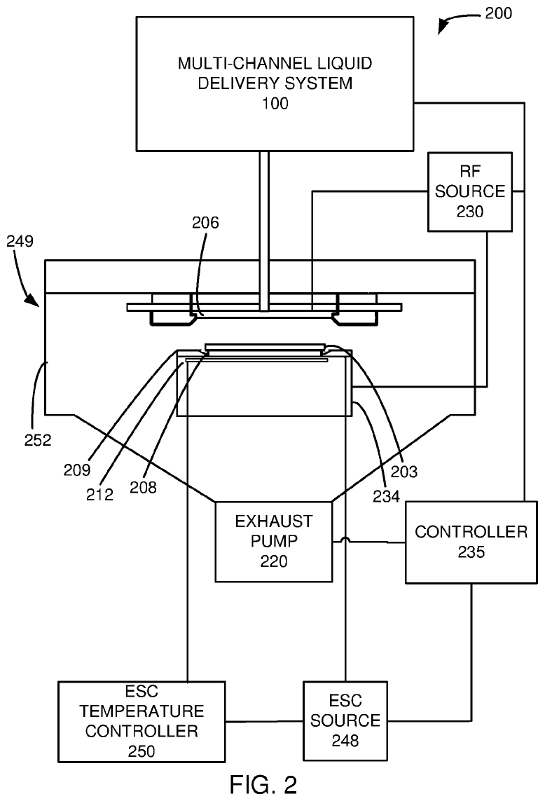

FIG. 2 is a schematic view of a plasma processing reactor in which an embodiment may be used for processing a wafer. In one or more embodiments, a plasma processing chamber 200 comprises a gas distribution plate 206 providing a gas inlet and an electrostatic chuck (ESC) 208, within a process chamber 249, enclosed by a chamber wall 252. In some embodiments, the ESC 208 may be another type of substrate support such as a pedestal. Within the process chamber 249, a wafer 203 is positioned over the ESC 208. The ESC 208 is a wafer support. An edge ring 209 surrounds the ESC 208. An ESC source 248 may provide a bias to the ESC 208. The multi-channel liquid delivery system 100 is connected to the process chamber 249 through the gas distribution plate 206. An ESC temperature controller 250 is connected to the ESC 208.

A radio frequency (RF) source 230 provides RF power to a lower electrode and/or an upper electrode. In this embodiment, the ESC 208 is the lower electrode and the gas distribution plate 206 is the upper electrode. In an exemplary embodiment, 400 kilohertz (kHz), 60 megahertz (MHz), 2 MHz, 13.56 MHz, and/or 27 MHz power sources make up the RF source 230 and the ESC source 248. In this embodiment, the upper electrode is grounded. In this embodiment, one generator is provided for each frequency. In other embodiments, the generators may be separate RF sources, or separate RF generators may be connected to different electrodes. For example, the upper electrode may have inner and outer electrodes connected to different RF sources. Other arrangements of RF sources and electrodes may be used in other embodiments. In other embodiments, an electrode may be an inductive coil. A controller 235 is controllably connected to the RF source 230, the ESC source 248, an exhaust pump 220, and the multi-channel liquid delivery system 100.

In an example for using the embodiment, a doped TEOS vapor is provided by the multi-channel liquid delivery system 100 into the process chamber 249 through the gas distribution plate 206. The first lock out tag out valve 120 allows liquid TEOS to flow from the first liquid input line 104 and the second liquid input line 108 through the first liquid filter 128 to the first input valve 136. The first input valve 136 allows the liquid TEOS to flow to the first liquid flow controller 152 and the second liquid flow controller 154. The first output valve 160 and the second output valve 162 allow the liquid TEOS to flow from the first liquid flow controller 152 and the second liquid flow controller 154 to the common manifold 170. The first liquid flow controller 152 and the second liquid flow controller 154 control the flow rate of the liquid TEOS. The first liquid flow controller 152 and the second liquid flow controller 154 allow for a higher and more controlled flow rate liquid TEOS than may be provided by a single liquid flow controller.

The second lock out tag out valve 122 allows liquid TEPo to flow from the third liquid input line 112 through the second liquid filter 130 to the second input valve 138. The second input valve 138 allows the liquid TEPo to flow to the third liquid flow controller 156. The third output valve 164 allows the liquid TEPo to flow from the third liquid flow controller 156 to the common manifold 170. The third liquid flow controller 156 controls the flow rate of the liquid TEPo.

The third lock out tag out valve 124 allows liquid TEB to flow from the fourth liquid input line 116 through the third liquid filter 132 to the third input valve 140. The third input valve 140 allows the liquid TEB to flow to the fourth liquid flow controller 158. The fourth output valve 166 allows the liquid TEB to flow from the fourth liquid flow controller 158 to the common manifold 170. The fourth liquid flow controller 158 controls the flow rate of the liquid TEB.

The liquid TEOS, liquid TEPo, and liquid TEB are mixed in the common manifold 170 providing a doped TEOS liquid mixture at defined ratios. The doped TEOS liquid mixture is provided to the vaporizer 172. The vaporizer 172 vaporizes the doped TEOS liquid mixture to form a doped TEOS vapor. The vaporizer 172 may include an atomizer. The atomizer may be an orifice. The doped TEOS vapor is provided through the gas distribution plate 206 into the process chamber 249. The RF source 230 provides power to form the doped TEOS vapor into a plasma. The doped TEOS plasma deposits a silicon oxide layer doped with boron and phosphorous on the wafer 203. The vapor and plasma may be stopped and other processes may be performed on the wafer 203. The wafer 203 may be removed and another wafer 203 may be processed.

After a plurality of wafers 203 is processed and purged from the chamber, the multi-channel liquid delivery system 100 may be purged. During the purge, the first, second, and third lockout tag out valves 120, 122, 124 may be closed and the first, second, and third input valves 136, 138, 140 may be closed. A purge gas is flowed from the purge gas input line 182 to the first, second, third, and fourth liquid flow controllers 152, 154, 156, 158.

The above embodiment allows for the deposition of a silicon oxide layer doped with boron and phosphorous. The first, second, third, and fourth liquid flow controllers 152, 154, 156, 158 control the ratios of the boron and phosphorous dopants to the silicon oxide. If a change in the percentage of a dopant is desired, the first, second, third, or fourth liquid flow controllers 152, 154, 156, 158 may be adjusted to obtain the desired percentage.

In other embodiments, a single liquid flow controller may be used in place of the first and second liquid flow controllers 152, 154. In addition, a single liquid input line may be used to provide liquid TEOS. In other embodiments, other liquids may be provided and mixed. In other embodiments, other deposition processes or etch processes or other wafer processing processes may be used. Some embodiments may add a device to mix liquids passing through the common manifold 170. Various embodiments are able to combine at least three different liquids.

In other embodiments, the first input line provides an undoped liquid tetraethyl orthosilicate. The second input line provides a liquid tetraethyl orthosilicate doped with a first dopant. The third input line provides a tetraethyl orthosilicate doped with a second dopant that is different than the first dopant. In some embodiments, the first dopant is phosphorous and the second dopant is boron.

In various embodiments, when maintenance is performed on the multi-channel liquid delivery system 100, the multi-channel liquid delivery system 100 is purged. The mixed liquids may be more difficult to purge. It is important to ensure that the multi-channel liquid delivery system 100 is completely purged before providing maintenance. In an embodiment, after the purging is completed, the multi-channel liquid delivery system 100 is sealed at a low pressure. The vapor manometer 178 is used to determine if the pressure in the multi-channel liquid delivery system 100 increases. If the pressure does not have a rate of rise of pressure above a threshold over time, then a complete purge is indicated. If the pressure increases over time above a threshold rate of rise, then additional purging is needed.

While this disclosure has been described in terms of several preferred embodiments, there are alterations, modifications, permutations, and various substitute equivalents, which fall within the scope of this disclosure. It should also be noted that there are many alternative ways of implementing the methods and apparatuses of the present disclosure. It is therefore intended that the following appended claims be interpreted as including all such alterations, modifications, permutations, and various substitute equivalents as fall within the true spirit and scope of the present disclosure.

What is claimed is:

1. An apparatus, comprising:
a first liquid input line;
a second liquid input line;
a third liquid input line;
a first liquid flow controller with an input in fluid contact with the first liquid input line;
a second liquid flow controller with an input in fluid contact with the second liquid input line;
a third liquid flow controller with an input in fluid contact with the third liquid input line;
a common manifold in fluid contact with an output of the first liquid flow controller and an output of the second liquid flow controller and an output of the third liquid flow controller; and
a vaporizer with an input in fluid contact with the common manifold.

2. The apparatus, as recited in claim 1, further comprising:
a plasma processing chamber; and
a gas inlet within the plasma processing chamber and in fluid contact with an output of the vaporizer.

3. The apparatus, as recited in claim 2, wherein the plasma processing chamber, comprises:
a process chamber; and
a wafer support for supporting a wafer within the process chamber.

4. The apparatus, as recited in claim 3 wherein the plasma processing chamber, further comprises a radio frequency source for providing radio frequency power into the process chamber to form a plasma from a gas.

5. The apparatus, as recited in claim 1, further comprising a purge gas input line, wherein the purge gas input line is in fluid contact with the first liquid flow controller, the second liquid flow controller, the third liquid flow controller, and the vaporizer.

6. The apparatus, as recited in claim 1, further comprising:
a first liquid filter in fluid communication between the first liquid input line and the first liquid flow controller;
a second liquid filter in fluid communication between the second liquid input line and the second liquid flow controller; and
a third liquid filter in fluid communication between the third liquid input line and the third liquid flow controller.

7. The apparatus, as recited in claim 1, further comprising an oxygen source in fluid contact with the input of the vaporizer.

8. The apparatus, as recited in claim 1, further comprising a manometer in fluid contact with the vaporizer.

9. The apparatus, as recited in claim 1, wherein the first liquid input line provides an undoped liquid tetraethyl orthosilicate, and wherein the second liquid input line provides a liquid tetraethyl orthosilicate doped with a first dopant, and wherein the third liquid input line provides a tetraethyl orthosilicate doped with a second dopant that is different than the first dopant.

10. The apparatus, as recited in claim 9, wherein the first dopant is phosphorous and wherein the second dopant is boron.

11. The apparatus, as recited in claim 1, further comprising:
a first lock out tag out valve connected to the first liquid input line;
a second lock out tag out valve connected to the second liquid input line; and
a third lock out tag out valve connected to the third liquid input line.
